(19) United States
(12) Patent Application Publication
(10) Pub. No.: US 2003/0235039 A1
(43) Pub. Date: Dec. 25, 2003

(54) Modulized power adaptor

(76) Inventor: I-Tai Chen, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/237,638

(22) Filed: Sep. 9, 2002

(30) Foreign Application Priority Data
Jun. 21, 2002 (TW) 91209405

(51) Int. Cl. H05K 7/00

(52) U.S. Cl. 361/728

(57) ABSTRACT

A modulized power adaptor is disclosed. By modulizing a conventional power adaptor and combining it with a port connection device, the modulized power adaptor is fabricated to resolve the problem of messy connection lines resulted from using or carrying such as a notebook computer. The modulized power adaptor comprises: an adaptor main unit; a port connection device installed on one side of the adaptor main unit; a power connection cord, wherein one end of the power connection cord is installed on another side of the adaptor main unit via a line collector located inside the adaptor main unit, and the other end of the power connection cord has a connecting plug; and a plug used for the connection with a plug-in hole of such as a notebook computer.

### FIELD OF THE INVENTION

The present invention relates to a modulized power adaptor, and more particularly, to a modulized power adaptor for use in a notebook computer having a port connection device.

### BACKGROUND OF THE INVENTION

With the broad application of various portable IT (Information Technology) products (such as notebook computers), the portable IT products are increasingly stressed on the operation conditions of conciseness and convenience, wherein power supply is one of the important issues. Currently, the products on the market generally utilize batteries, or the method of electrically connecting to AC/DC power adaptors, to provide the power for the portable IT products.

However, when a conventional power adaptor is used to supply power for portable IT products, since the connection lines related to the power adaptor is quite messy, it is inconvenient for users to operate or carry the portable IT products. Referring to FIG. 1, FIG. 1 is a schematic diagram showing the structure of a conventional power adaptor. Generally, a conventional power adaptor is composed of an adaptor main unit 10, a power connection cord 50 and a target-connecting element 30, wherein the power connection cord 50 is electrically connected to a power source (not shown) via a plug, for example, an AC power source of 110 volt or 220 volt, an power source of car cigar-lighter, etc. The target-connecting element 30 is electrically connected to a target IT product (not shown), such as a power inlet of a notebook computer. When the conventional power adaptor is used for providing power, the power enters the adaptor main unit 10 via the power connection cord 50. After the current thereof is converted to the specification applicable to the target IT product, the converted current is transmitted to the target IT product via the target-connecting element 30, thereby providing the power for the target IT product. Since the power connection cord 50 and the target-connecting element 30 are quite long in length, and the adaptor main unit 10 also occupies certain space, thus, when the conventional power adaptor is either operated or carried, the power connection cord 50 and the target-connecting element 30 both make the connection lines thereof very messy. Additionally, the size of the adaptor main unit 10 causes users more inconvenience and troubling.

### SUMMARY OF THE INVENTION

In view of the aforementioned background, since the connection lines of the conventional power adaptor are quite messy, users have a lot of inconvenience while operating or carrying the conventional power adaptor.

Hence, it is an object of the present invention to provide a modulized power adaptor, for providing concise and convenient conditions for users to carry or operate the power adaptor, thus overcoming the problem of messy connection lines caused by carrying or operating the conventional power adaptor.

According to the aforementioned object, the present invention provides a modulized power adaptor. The modulized power adaptor of the present invention comprises: an adaptor main unit, used for converting power (such as power from AC power source of 110 volt or 220 volt, or power source of car cigar-lighter, etc.) to target power applicable to a target IT product; a port connection device, wherein the port connection device is installed on a first side of the adaptor main unit, and the port connection device can be inserted into a battery port or a CD ROM port, etc., of the target IT product, for supplying power to the target IT product; a power connection cord, wherein one end of the power connection cord is installed on a second side of the adaptor main unit, and further, can be installed on the second side via a cord collector located inside the adaptor main unit, and the other end of the power connection cord has a first plug used for electrically connecting to a power source; and a second plug, wherein the second plug is installed by a rotatable way inside a recess of a third side of the adaptor main unit. When the port connection device is not used for supplying power, the second plug can be connected to an inlet of the target IT product for supplying power. The second plug can be hidden inside the recess on the third side of the adaptor main unit.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic diagram showing the structure of a conventional power adaptor; and

FIG. 2 is a schematic diagram showing the structure of a power adaptor, according to a preferred embodiment of the present invention.

### DETAILED DESCRIPTION OF THE PREFERRED EMBODIMENT

The present invention discloses a modulized power adaptor. The present invention is to modulize a conventional power adaptor with the combination of a port connection device, thereby overcoming the problem of messy connection lines caused by operating and carrying, for example, a notebook computer.

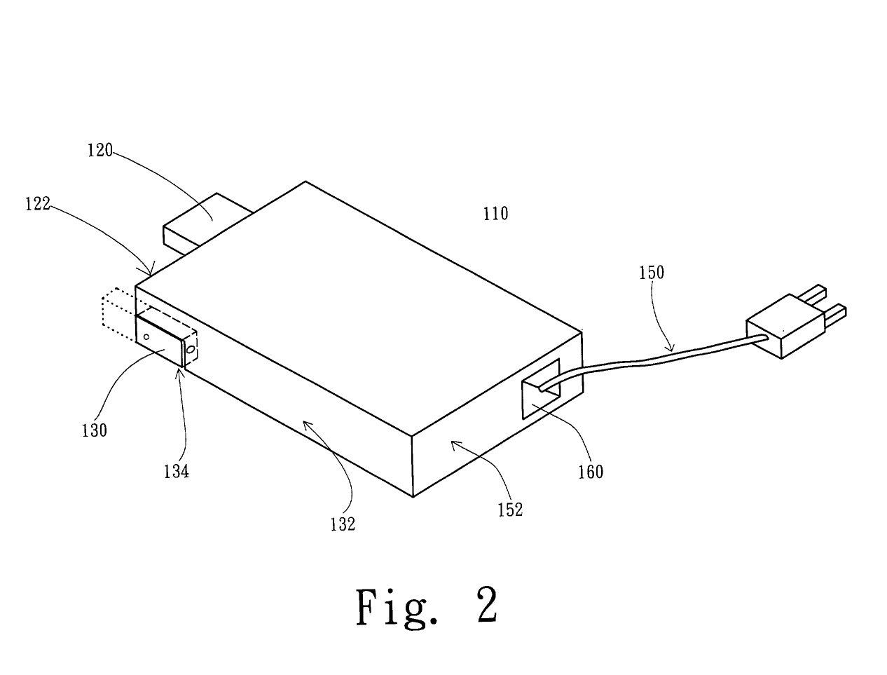

Referring to FIG. 2, FIG. 2 is a schematic diagram showing the structure of a power adaptor, according to a preferred embodiment of the present invention. The modulized power adaptor of the present invention comprises: an adaptor main unit 110; a port connection device 120, wherein the port connection device 120 is installed on a first side 122 of the adaptor main unit 110; a power connection cord 150, wherein one end of the power connection cord 150 is installed on a second side 152 of the adaptor main unit 110, an the other end of the power connection cord 150 has a plug that can be electrically connected to a power source; and a plug 130, wherein the plug 130 is installed by a rotatable way inside a recess 134 of a third side 132 of the adaptor main unit 110.

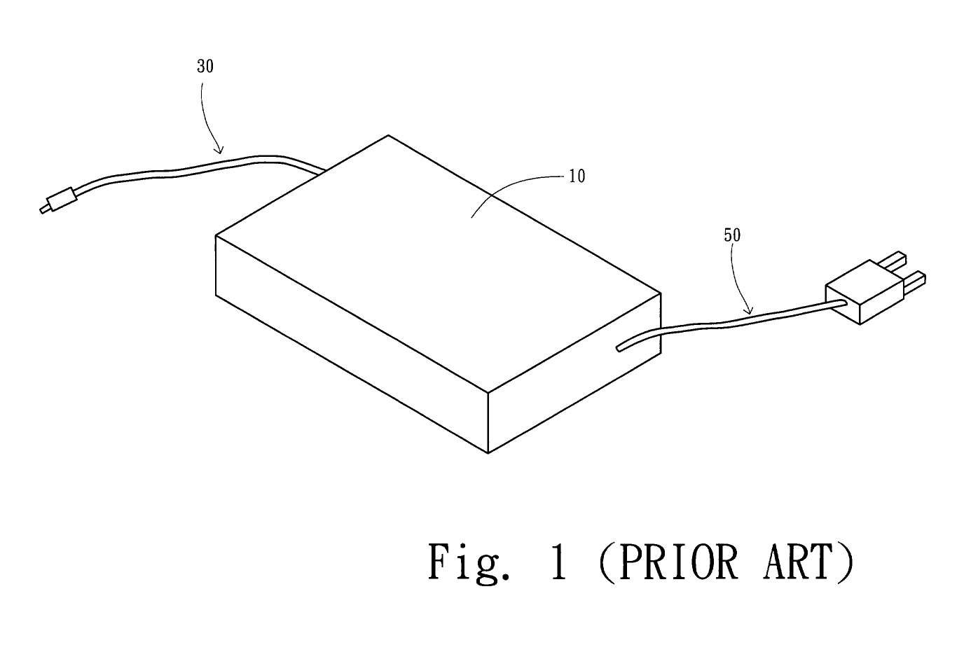

Please continuously refer to FIG. 2. The adaptor main unit 110 of the present invention is used for converting power to a target power whose specification is applicable to a target IT product (not shown), wherein the target IT product is a portable IT product, such as a notebook computer, etc. The port connection device 120 is used for being inserted into a port (not shown; such as a battery port or a CD ROM port, etc.) of the target IT product, so as to supply power to the target IT product. When the port connection device 120 is used for supplying power, the current enters the adaptor main unit 110 via the power connection cord 150. After the current is converted to the specification applicable to the target IT product, the converted current is transmitted to the port of the target IT product via the port connection device 120, so as to provide power to the target IT product. The port is located inside the target IT product. Thus, when the port of the target IT product is used for supplying power, the power adaptor of the present invention can be combined with the target IT product as one piece, so that the conventional target-connecting element 30 as shown in FIG. 1 can be omitted, and the entire necessary connection can be completed by merely electrically connecting the power connection cord 150 to the plug of power source (such the plug of AC power source of 110 volt or 220 volt, the plug of car cigar-lighter, etc.).

The modulized power adaptor of the present invention further comprises a cord collector 160, wherein one end of the power connection cord 150 first penetrates the second side 152 of the adaptor main unit 110, and then is connected to the cord collector 160. The structure of the cord collector 160 is similar to that of the cord-collecting device installed on a vacuum machine or a rice cooker, and the design thereof can be either the mechanism of pull-release-and-wind or that of winding by pushing a collecting switch. The collector 160 is used for adjusting the length of the power connection cord 150 to a proper one, so that the problem of messy connection lines of the conventional power adaptor can be effectively overcome.

On the other hand, when the port connection device 120 is not or cannot be used for supplying power, for example, the ports such as the battery port and the CD ROM port are all occupied, the present invention also can use the way adopted by conventional power adaptor to supply power, i.e. the way of using the plug 130 for connecting the modulized power adaptor of the present invention to the power inlet (plug-in hole) of the target IT product. When the plug 130 is not used, the plug 130 can further be completely hidden inside the recess 134 of the third side 132 of the adaptor main unit 110. Therefore, while in use, the plug 130 has to be rotated with a certain degree so as to be exposed, such as shown with the dash line in FIG. 2.

Hence, it is an advantage of the present invention to provide a modulized power adaptor. By applying the present invention, while operating or carrying a power adaptor, users can have the operation conditions of conciseness and convenience, thus overcoming the problem of messy connection lines caused by carrying or operating the conventional power adaptor.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structures.

What is claimed is:

1. A modulized power adaptor, used for a target information technology (IT) product, the modulized power adaptor comprising:
an adaptor main unit;
a port connection device, installed on the adaptor main unit, wherein the port connection device is used for being inserted into a port of the target IT product; and
a power connection device, installed on the adaptor main unit, wherein one end of the power connection device has a plug, wherein the power connection device is received in the adaptor main unit when not being used.

2. The modulized power adaptor of claim 1, wherein the port connection device is installed on a first side of the adaptor main unit.

3. The modulized power adaptor of claim 1, wherein the power connection device is a power connection cord.

4. The modulized power adaptor of claim 3, wherein the other end of the power connection cord is installed on a second side of the adaptor main unit.

5. The modulized power adaptor of claim 4, wherein the modulized power adaptor further comprises a cord collector for receiving the power connection cord into the adaptor main unit, wherein, after penetrating the second side of the adaptor main unit, the other end of the power connection cord is connected to the cord collector for adjusting the length of the power connection cord to a proper length.

6. The modulized power adaptor of claim 1, wherein the power connection device is a power connection plug.

7. The modulized power adaptor of claim 6, wherein the power connection plug is installed on a third side of the adaptor main unit by a rotatable way.

8. The modulized power adaptor of claim 7, wherein the third side has a recess for receiving the power connection plug into the adaptor main unit, and the power connection plug is installed inside the recess of the third side, and can be hidden inside the third side of the adaptor main unit.

9. The modulized power adaptor of claim 1, wherein the target IT product is a notebook computer.

10. The modulized power adaptor of claim 1, wherein the port of the target IT product is a battery port.

11. The modulized power adaptor of claim 1, wherein the port of the target IT product is a CD ROM port.

12. The modulized power adaptor of claim 1, wherein the power connection plug is used for connecting the modulized power adaptor to a power inlet of the target IT product.

13. A modulized power adaptor, used for a target IT product, the modulized power adaptor comprising:
an adaptor main unit;
a port connection device, wherein the port connection device is installed on a first side of the adaptor main unit, and is used to be inserted into a port of the target IT product;
a power connection cord, wherein, after penetrating a second side of the adaptor main unit, one end of the power connection cord has a first plug; and
a second plug, installed on a third side of the adaptor main unit, wherein the second plug is used for connecting the modulized power adaptor to an power inlet of the target IT product, wherein the power connection cord is received in the adaptor main unit when not being used, and the second plug is received in the adaptor main unit when not being used.

14. The modulized power adaptor of claim 13, further comprising a cord collector for receiving the power connection cord into the adaptor main unit, wherein, after penetrating the second side of the adaptor main unit, the other end of the power connection cord is connected to the cord collector for adjusting the length of the power connection cord to a proper length.

15. The modulized power adaptor of claim 13, wherein the third side has a recess, and the second plug is installed inside the recess of the third side, and can be hidden inside the third side of the adaptor main unit.

16. The modulized power adaptor of claim 13, wherein the target IT product is a notebook computer.

17. The modulized power adaptor of claim 13, wherein the port of the target IT product is a battery port.

18. The modulized power adaptor of claim 13, wherein the port of the target IT product is a CD ROM port.
